(19) United States
(12) Patent Application Publication
(10) Pub. No.: US 2017/0345921 A1
(43) Pub. Date: Nov. 30, 2017

(54) POWER DEVICE AND METHOD FOR FABRICATING THEREOF

(71) Applicant: EPISTAR CORPORATION, HSINCHU (TW)

(72) Inventor: Tian-Jing Feng, Taichung (TW)

(21) Appl. No.: 15/168,114

(22) Filed: May 30, 2016

(51) Int. Cl. H01L 29/778; H01L 29/06; H01L 29/20; H01L 29/66

(52) U.S. Cl. CPC H01L 29/7787; H01L 29/66462; H01L 29/0657; H01L 29/2003

(57) ABSTRACT

A power device having a patterned three-dimensional gate geometry is fabricated and described. The power device achieved increased effective gate width and increased channel conductivity per unit length. It includes at least a channel layer, a barrier layer, a dielectric layer, a gate disposed on the dielectric layer, dielectric layer disposed on the barrier layer and the channel layer, respectively. Gate includes protruding sections and extending sections directly contacting the dielectric layer. Dielectric layer includes a repeating rectangular-wave structure. The dielectric layer forms a gate oxide directly contacting trenches of channel layer. Alternatively, gate oxide can be disposed directly on a p-doped GaN filled region which includes an alternating repeating rectangular-wave structure.

### BACKGROUND OF THE INVENTION

### (a) Field of the Invention

The present application is related to a high-electron-mobility transistor (HEMT) power device, and more particularly, to a gallium nitride (GaN) high-electron-mobility transistor (HEMT) having a patterned three-dimensional gate geometry.

### (b) Description of the Prior Art

Gallium nitride (GaN) had been used extensively as a light illuminating material, and has been used as a main material for fabricating commercial blue LEDs. Meanwhile, GaN is also known to be a material of wider bandgap to be used for fabricating a high-electron-mobility transistor (HEMT).

The high-electron-mobility transistor (HEMT) is a field-effect transistor (FET) that has superior electron mobility, high breakdown voltage, and used for creating switching power devices for various applications, such as for motor drive and power supply applications. HEMT made from GaN typically are of AlGaN/GaN heterostructure. GaN is a material that produces spontaneous polarization effect. Due to difference in lattice constants, an AlGaN barrier layer grown on a GaN channel layer can produce piezoelectric polarization effect. With these polarization effects, a two-dimensional electron gas (2DEG) channel region is formed in the GaN channel layer near an interface of the GaN channel layer and the AlGaN barrier layer, in which a gas of electrons is free to move in two dimensions.

An AlGaN/GaN HEMT device can be operating under unidirectional mode, and can achieve superior or increased current density by shortening of a spacing between a drain and a gate for lowering the on-state resistance, but at the same time affecting breakdown voltage. Based on existing techniques for increasing the effective width of the gate for achieving increased channel conductivity per unit length, a foreseeable optimization limitation can be reached. Furthermore, by adapting a recessed gate design for fabricating a normally-OFF device would typically lead to the increase of the on-state resistance R_{DS(on)} and the lowering of the current density of the normally-OFF device. As a result, there is room for improvement in the related art.

### SUMMARY OF THE INVENTION

An object of the present application is to provide a high-electron-mobility transistor (HEMT) having a patterned three-dimensional gate geometry.

Another object of the present application is to provide a HEMT that is a AlGaN/GaN HEMT having a patterned three-dimensional gate geometry for achieving increased effective gate width so as to obtain increased channel conductivity per unit length.

Another object is to provide one or more methods of fabricating the HEMT that is a power device of the embodiments of present application.

To achieve one or more of the objects, in an embodiment of present application, a power device, which is a HEMT having the patterned three-dimensional gate geometry, is fabricated and described, in which the power device includes a substrate layer, a buffer layer, a channel layer disposed on the buffer layer and including a first group IIIA-VA compound semiconductor material, a barrier layer disposed on the channel layer and including a second group IIIA-VA compound semiconductor material, a dielectric layer, a gate disposed on the dielectric layer, the dielectric layer disposed on the barrier layer and the channel layer, respectively, a source electrode, and a drain electrode.

In accordance with the embodiment of present application, the channel layer includes a plurality of trenches, the dielectric layer directly contacts the channel layer and fills the plurality of trenches of the channel layer, and the gate includes a plurality of protruding sections and a plurality of extending sections directly contacting the dielectric layer.

In accordance with the embodiment of present application, the channel layer is an undoped GaN (u-GaN) layer, the barrier layer is an AlGaN layer.

In accordance with the embodiment of present application, the dielectric layer includes a repeating rectangular-wave structure conformally disposed along a direction substantially parallel with the source electrode and the drain electrode, respectively. The dielectric layer forms a gate oxide, and the gate oxide directly contacts a top surface of the channel layer and the plurality of trenches of the channel layer, respectively. The gate includes a gate width in a direction substantially parallel with the source electrode and the drain electrode.

In accordance with the embodiment of present application, an interface between the dielectric layer and the channel layer includes side interface portions and planar interface portions corresponding to the plurality of trenches, and a ratio of an area of the side interface portions to that of the planar interface portions is greater than 0.2.

In accordance with the embodiment of present application, a gate width is about 2200 nm, and a depth of one of the trenches of the channel layer is about 50 nm.

To achieve one or more of the objects, in an another embodiment of present application, the power device is fabricated and described, in which the power device can be a high-electron-mobility transistor (HEMT) which includes a substrate layer, a buffer layer, a channel layer disposed on the buffer layer and including a first group IIIA-VA compound semiconductor material, a barrier layer disposed on the channel layer and including a second group IIIA-VA compound semiconductor material, a dielectric layer, a p-doped first group IIIA-VA compound semiconductor material filled region, a gate disposed on the dielectric layer, the dielectric layer disposed on the barrier layer and the p-doped first group IIIA-VA compound semiconductor material filled region, respectively, a source electrode, and a drain electrode.

In accordance with the another embodiment of present application, the channel layer includes a plurality of trenches, the dielectric layer directly contacts the p-doped first group IIIA-VA compound semiconductor material filled region, the p-doped first group IIIA-VA compound semiconductor material filled region is conformally disposed on and directly contacting a top surface of the channel layer and filling the plurality of trenches of the channel layer, the gate includes a plurality of protruding sections and a plurality of extending sections directly contacting the dielectric layer, respectively.

In accordance with the another embodiment of present application, the channel layer includes an u-GaN layer, the barrier layer includes an AlGaN layer, and the p-doped first group IIIA-VA compound semiconductor material filled region is made of p-GaN.

In accordance with the another embodiment of present application, the dielectric layer forms a gate oxide, and the gate oxide is disposed directly on the p-doped first group IIIA-VA compound semiconductor material filled region and in the plurality of trenches of the channel layer. In addition, the dielectric layer includes a repeating rectangular-wave structure conformally disposed along a direction substantially parallel with the source electrode and the drain electrode respectively, the p-doped first group IIIA-VA compound semiconductor material filled region includes an alternating repeating rectangular-wave structure conformally disposed along the direction substantially parallel with the source electrode and the drain electrode, respectively.

To achieve one or more of the objects, in the another embodiment of present application, upon the gate being placed or configured under positive bias voltage, the p-doped first group IIIA-VA compound semiconductor material filled region is made of p-GaN and providing inversion of electrons for conducting current flow. Additionally, an interface formed between the p-doped first group IIIA-VA compound semiconductor material filled region and the dielectric layer includes side interface portions and planar interface portions corresponding to the repeating rectangular-wave structure of the dielectric layer, and a ratio of an area of the side interface portions to that of the planar interface portions is greater than 0.2.

In accordance with the embodiments of present application, a method for fabricating a power device, is provided, which includes the following steps: in step (a), a buffer layer, a channel layer, and a barrier layer are grown on a substrate layer in sequential order; in step (b), a first trench is formed by etching the barrier layer; in step (c), the channel layer is patterned to form a plurality of second trenches therein using photolithography and etching; in step (d), a dielectric layer is grown in a gate region in a conformal manner using photolithography; in step (e), a gate is formed on the dielectric layer in the gate region; and in step (f), a source electrode and a drain electrode are respectively formed on the barrier layer.

In accordance with the method for fabricating the power device, the channel layer includes a first group IIIA-VA compound semiconductor material; the barrier layer includes a second group IIIA-VA compound semiconductor material; the gate includes a plurality of protruding sections and a plurality of extending sections directly contacting the dielectric layer, the dielectric layer includes a repeating rectangular-wave structure conformally disposed along a direction substantially parallel with the source electrode and the drain electrode, respectively, in which the protruding sections of the gate fill the repeating rectangular-wave structure of the dielectric layer.

In accordance with the method for fabricating the power device, the channel layer includes an undoped GaN layer, the barrier layer includes an AlGaN layer, and the power device fabricated includes a high-electron-mobility transistor (HEMT).

In accordance with the method for fabricating the power device, in step (b), the first trench is formed by etching through the barrier layer to stop on a top surface of the channel layer.

In accordance with the method for fabricating the power device, in step (d), the dielectric layer directly contacts a top surface of the channel layer and fills the plurality of second trenches of the channel layer.

In accordance with the method for fabricating the power device, wherein in the step (b), the first trench is formed by etching the barrier layer and a portion of the channel layer.

In accordance with the method for fabricating the power device, between the step (c) and the step (d), the method further includes a step of regrowing a p-doped first group IIIA-VA compound semiconductor material filled region in the gate region in a conformal manner directly contacting the channel layer and filling the plurality of second trenches of the channel layer, and in the step (d), the dielectric layer directly contacts the p-doped first group IIIA-VA compound semiconductor material conformal filled region.

In accordance with the method for fabricating the power device, the first trench is formed by dry etching, and the p-doped first group IIIA-VA compound semiconductor material filled region is a conformally filled structure made of p-GaN.

Advantages of the invention will be set forth in part in the description which follows, and in part will be obvious from the description, or may be learned by practice of the invention.

These and other objects of the present application will no doubt become obvious to those of ordinary skill in the art after reading the following detailed description of the preferred embodiment that is illustrated in the various figures and drawings.

### BRIEF DESCRIPTION OF THE DRAWINGS

The present application is illustrated by way of example and not limited by the figures of the accompanying drawings in which same references indicate similar elements. Many aspects of the disclosure can be better understood with reference to the following drawings. Moreover, in the drawings same reference numerals designate corresponding elements throughout. Wherever possible, the same reference numerals are used throughout the drawings to refer to the same or similar elements of an embodiment.

FIGS. 1-6 are three-dimensional perspective views illustrating sequential steps for a method for fabricating a power device according to an embodiment of present application.

FIGS. 7, 9 and 10 are cross-sectional views showing the gate geometries and the dielectric layer structures in multiple axes directions of the power device according to the embodiment of present application, in which FIGS. 9 and 10 further showing patterning geometries and structures of the channel layer according to the embodiment of present application.

FIG. 8 is a 3-dimensional perspective view showing a fabricated HEMT power device having the patterned three-dimensional gate geometry according to the embodiment of present application.

FIGS. 11-17 are three-dimensional perspective views illustrating sequential steps for a method for fabricating a power device according to an another embodiment of present application.

FIGS. 18, 20 and 21 are cross-sectional views showing the gate geometries and structures and a p-doped first group IIIA-VA compound semiconductor material filled region in multiple axes directions of the power device according to the another embodiment of present application, in which FIGS. 20 and 21 further showing patterning geometries and structures of the channel layer and the p-doped first group IIIA-VA compound semiconductor material filled region according to the another embodiment of present application.

FIG. 19 is a three-dimensional perspective view showing a fabricated HEMT power device according to the another embodiment of present application having a patterned three-dimensional gate geometry.

FIG. 22 is an enlarged partial cross-sectional view of FIG. 7 showing various patterning structures and dimensions directed to the channel layer and the dielectric layer, respectively.

### DETAILED DESCRIPTION OF THE PREFERRED EMBODIMENTS

The present application will now be described more specifically with reference to the following embodiments. It is to be noted that the following descriptions of the embodiments of this invention are presented herein for purpose of illustration and description only. It is not intended to be exhaustive or to be limited to the precise form disclosed.

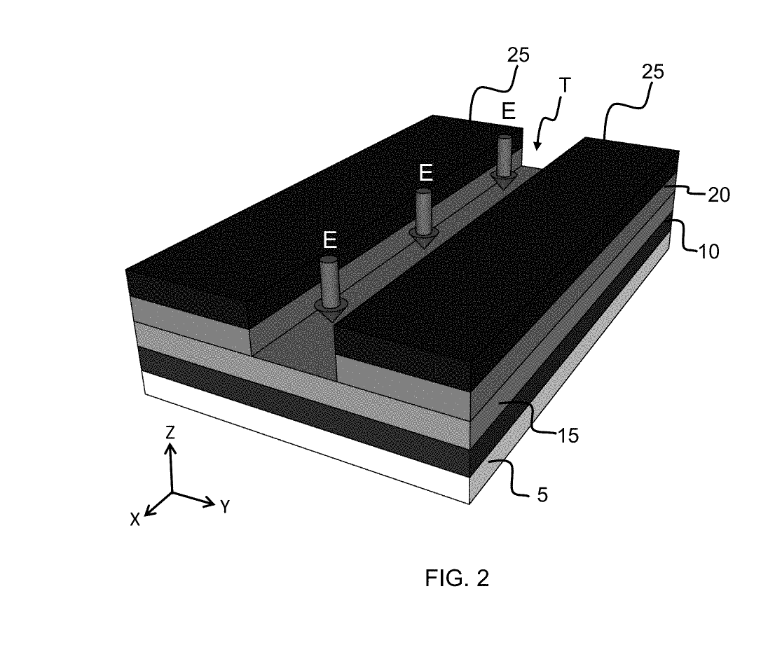

As shown in FIGS. 2-10, 12-13, 15-22, a three-dimensional Cartesian coordinate system, with axis lines (or axis directions) X, Y and Z, oriented as shown by the arrows are utilized for describing various directions and orientations of elements and device structures to the following embodiments.

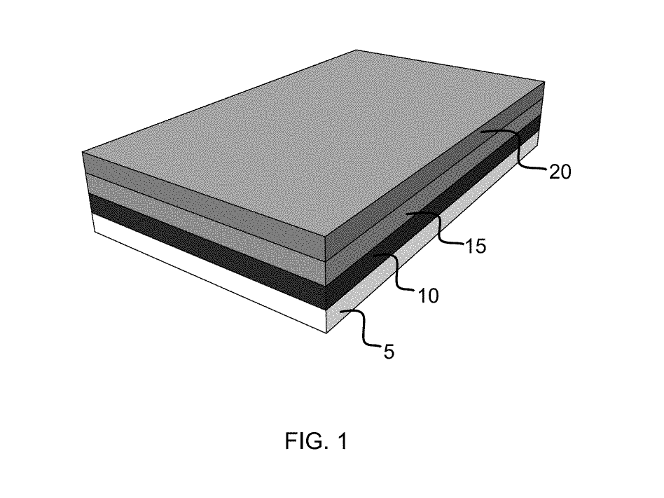

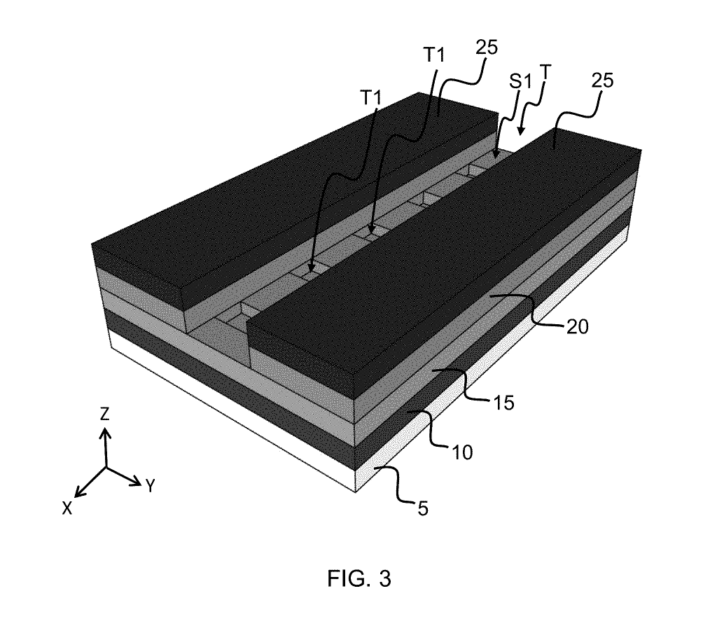

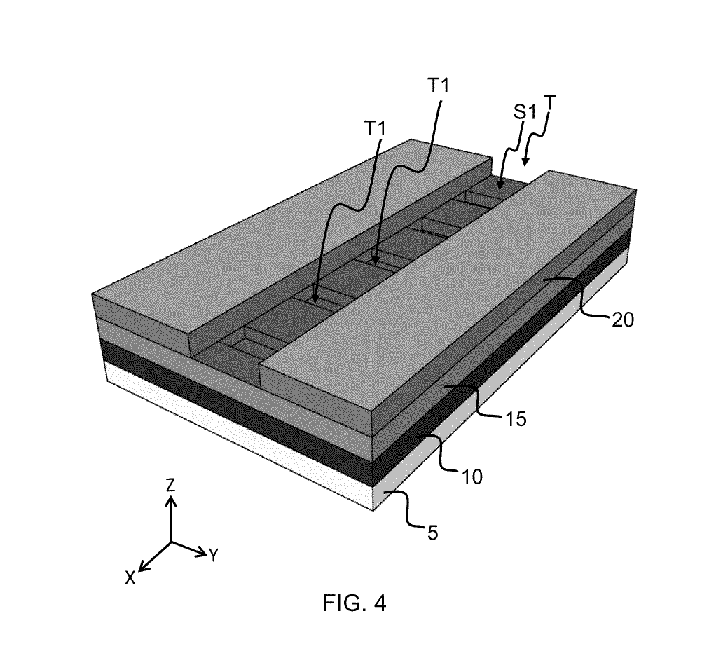

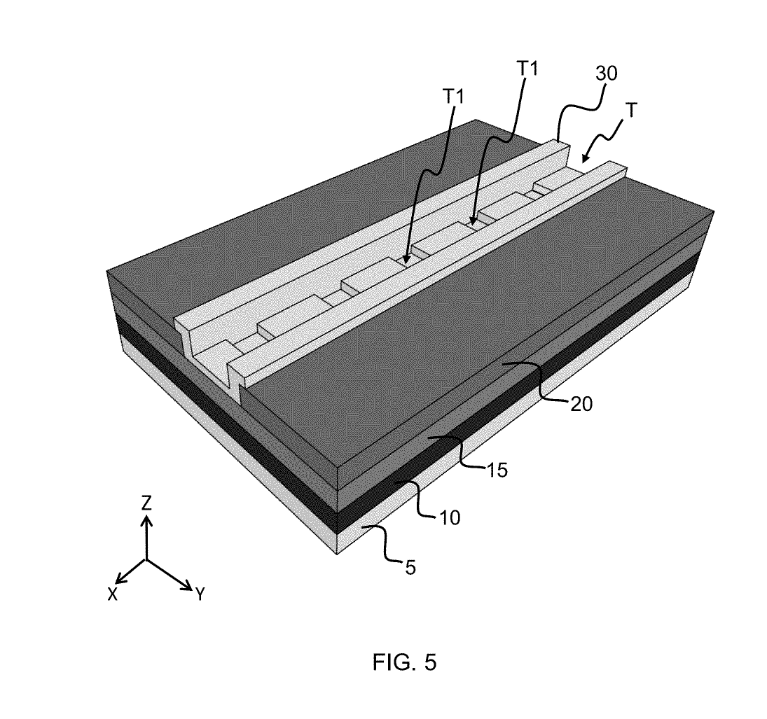

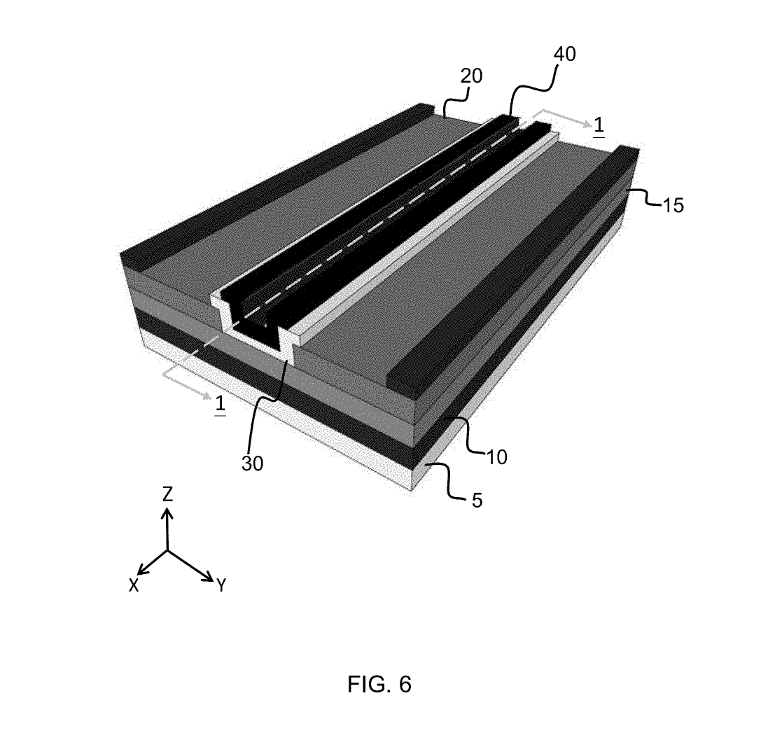

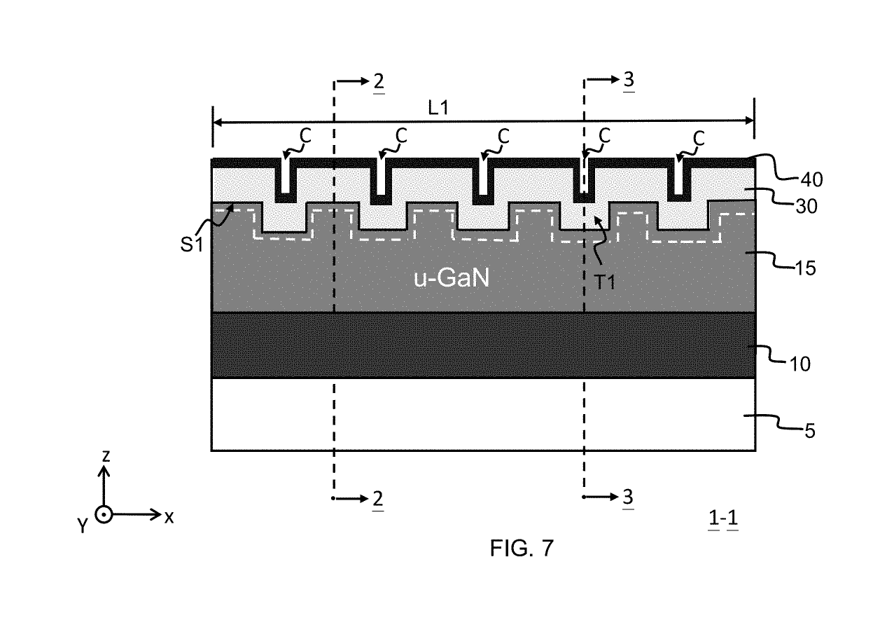

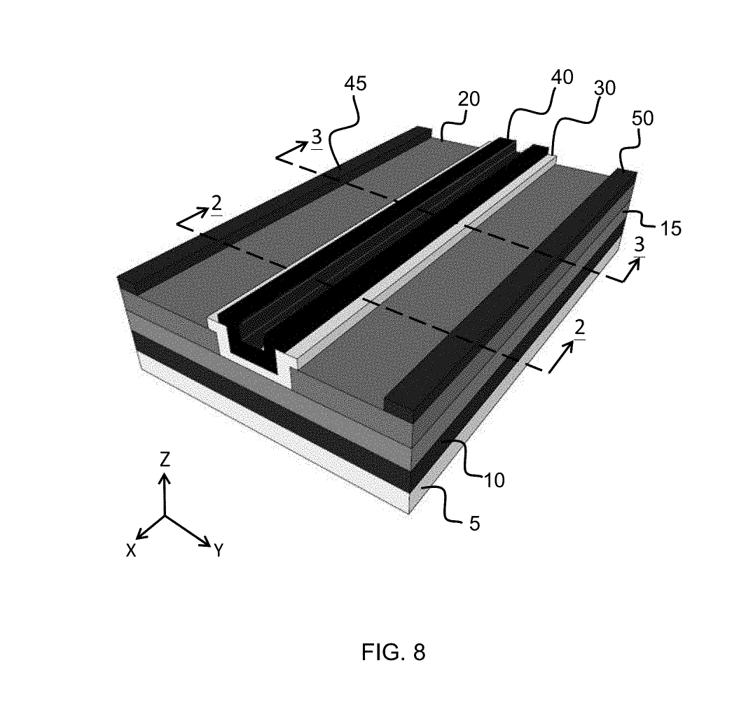

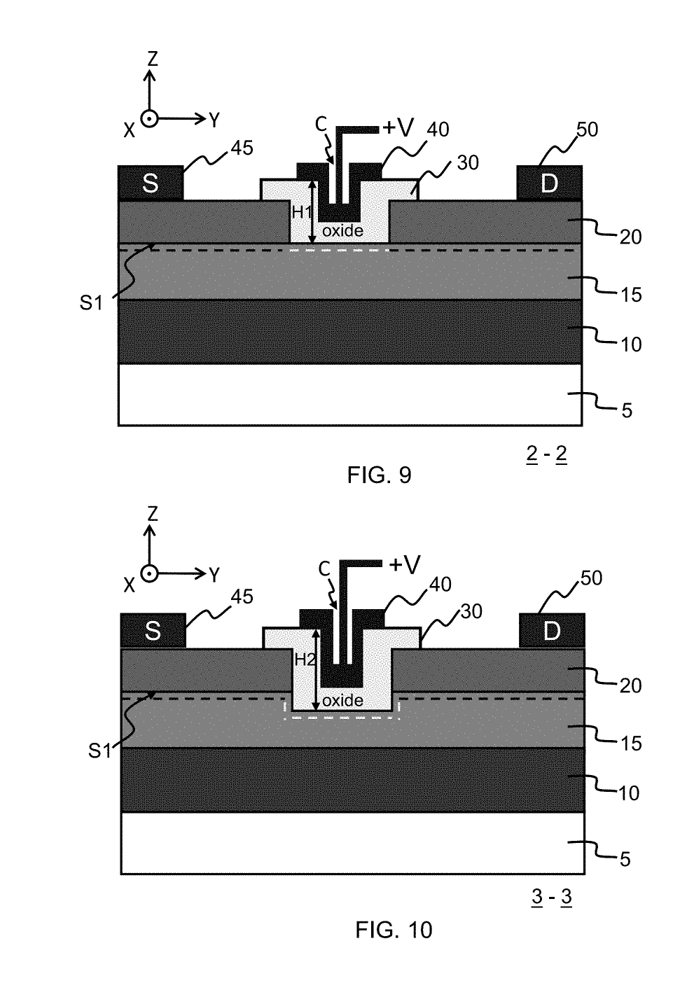

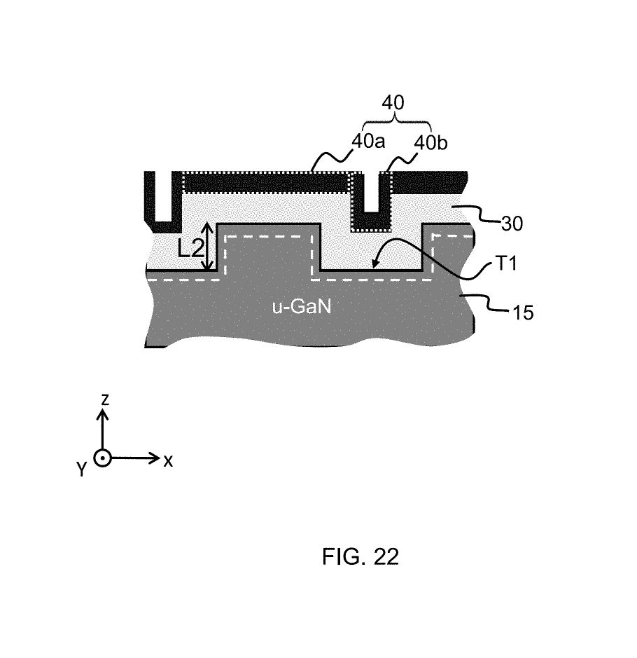

In accordance with a method for fabricating a power device of an embodiment of present application, referring to FIGS. 1-10 and 22, a power device, which is a HEMT having a patterned three-dimensional gate geometry, is fabricated by means of the following steps. As shown in FIG. 1, in step (a), a buffer layer 10, a channel layer 15, and a barrier layer 20 are respectively grown on a substrate layer 5 in sequential order. The substrate layer 5 can be, for example, silicon (Si) substrate. The buffer layer 10 can include one or more sequential group-III nitride layers, with the group-III including one or more of In, Ga, and Al, such as, for example, gallium nitride (GaN), with a thickness about several micrometers. Meanwhile, the channel layer 15 can include a first group IIIA-VA compound semiconductor material, such for example, an u-GaN layer 15, with a thickness about 50 nm to 500 nm, and the barrier layer 20 can be a second group IIIA-VA compound semiconductor material, for example, an AlGaN layer 20, with a thickness about 10 nm to 50 nm. Later as shown in FIG. 2, in step (b), a trench T is formed by an etching process E such as, for example, a dry-etching process E (shown as three-dimensional arrow structures in FIG. 2) through the barrier layer 20 to stop on a top surface of the channel layer 15 using photolithography techniques in combination with a hard mask 25, for example, a SiO₂ hard mask 25 formed by chemical vapor deposition. As shown in FIGS. 3, 4, and 22, in step (c), the channel layer 15 is further etched and patterned to form a plurality of trenches T1 of a trench depth L2 (referring to FIG. 22) in the trench T that are respectively configured and arranged along an x-axis direction using photolithography and dry etching technique. Then, as shown in FIG. 4, the SiO₂ hard mask 25 is removed using wet etching with hydrofluoric (HF) acid. Referring to FIG. 5 showing step (d), a dielectric layer 30 is grown or formed in a gate region (not labeled) corresponding to locations of the trench T and the plurality of trenches T1 in a conformal manner along the x-axis direction directly contacting the channel layer 15 and filling the trench T and the plurality of trenches T1 of the channel layer 15 using photolithography, in which the dielectric layer 30 can be silicon dioxide material, silicon nitride material, or other high-k dielectric material, and is deposited by an atomic layer deposition (ALD) process or a chemical vapor deposition (CVD) process. Thickness of the dielectric layer 30 can be 10 nm to 50 nm. Meanwhile, FIGS. 7, 9 and 10 are cross-sectional views taken along sections 1-1, 2-2, and 3-3 of the power device shown in FIGS. 6-8, respectively. In steps (e) and (f), a gate 40 is formed on the dielectric layer 30 in the gate region (not labelled) and includes a gate width L1, and a source electrode 45 and a drain electrode 50 are respectively formed on the barrier layer 20. In particular as shown in FIGS. 9-10 and 22, the gate 40 is extended along along the x-axis direction that is substantially parallel with the source electrode 45 and the drain electrode 50, respectively, in which the gate 40 includes a plurality of protruding sections 40b and a plurality of extending sections 40a directly contacting the dielectric layer 30. Furthermore, the dielectric layer 30 includes a repeating rectangular-wave structure conformally disposed along the x-axis direction, in which the protruding sections 40b of the gate 40 fill the repeating rectangular-wave structure of the dielectric layer 30 as shown in FIGS. 6-10 and 22. The gate 40 can be made of a metal or alloy such as, for example, copper, nickel/gold, or tungsten. The source electrode 45 and the drain electrode 50 can be made of the same material, which can be metal, such as, for example, titanium, copper, silver, tungsten, aluminum, gold, or any of their compounds. In the illustrated embodiment as shown in FIGS. 9 and 10, the dielectric layer 30 forms a gate oxide, which is designated as “oxide” in the illustrated embodiment of FIGS. 9 and 10, and the gate oxide (oxide) directly contacts a top surface S1 of the channel layer 15 and the plurality of trenches T1 of the channel layer 15, respectively. Due to a difference in lattice constants, the barrier layer 20 grown on the u-GaN channel layer 15 can produce a piezoelectric polarization effect. Additionally, the material of the u-GaN channel layer 15, and the material of the barrier layer 20, for example, AlGaN can produce spontaneous polarization effect. With these polarization effects, a two-dimensional electron gas is formed in the u-GaN channel layer 15 near an interface of the u-GaN channel layer 15 and the barrier layer 20, as shown in FIGS. 9-10 indicated by the black broken lines. Additionally, upon the gate 40 being exerted under a positive bias voltage, due to the interaction between the u-GaN channel layer 15 and the dielectric layer 30, electrons, as shown in FIGS. 7 and 9-10 indicated by the white broken line, can accumulate near an interface of the u-GaN channel layer 15 and the dielectric layer 30. That is to say, there is an accumulation of electrons in the u-GaN channel layer 15 near an interface of the u-GaN channel layer 15 and the dielectric layer 30. In the embodiment, because the power device includes the plurality of trenches T1, thus the interface of the u-GaN channel layer 15 and the dielectric layer 30 includes side interface portions and planar interface portions corresponding to the plurality of trenches T1. Specifically, in the embodiment, a ratio of a total area of the side interface portions to that of the planar interface portions can be L2×2×m/L1, wherein L2 (referring to FIG. 22) is a depth of one of the plurality of trenches T1, m is a number of the plurality of trenches T1, and L1 is the gate width. In the embodiment, L2 can be 50 nm, the gate width L1 can be 2200 nm, m can be 5, and the above mentioned ratio can be greater than 0.2. Comparing the power device of the application with a power device without patterned trenches in a channel layer, since electrons of the power device of the application can further accumulate near the side interface portions, thus an increased current ratio of the application can be L2×2×m/L1 corresponding to the ratio mentioned above. Thus the ideal increased current ratio can be approximately 0.2 which means the current is increased by at least 20%. However, in consideration other conditions, for example, the mobility of the accumulated electrons in a z-axis different from that of in a x-axis, the increased current ratio can be approximately increased by at least 0.1. Notably, the cavity structures C of the gate 40 (in the middle regions thereof) as shown and identified in FIG. 7, as well as shown in FIGS. 9 and 10 are not visible in FIGS. 6 and 8 (for example, in FIG. 7, there are 5 cavity structures for the gate 40), due to the fact that other portion of the gate 40 in FIGS. 6 and 8 obstruct direct view of these cavity structures C.

Referring to FIGS. 8 and 22, at the completion of the fabrication method of the power device, the power device of the HEMT according to the embodiment of present application having a patterned 3-dimensional gate geometry is fabricated. The power device of the illustrated embodiment includes a substrate layer 5, a buffer layer 10, a channel layer 15 disposed on the buffer layer 10, a barrier layer 20 disposed on the channel layer 15, a dielectric layer 30, a gate 40 disposed on the dielectric layer 30, the dielectric layer 30 disposed on the barrier layer 20 and the channel layer 15, respectively, a source electrode 45, and a drain electrode 50. The channel layer 15 includes a plurality of trenches T1, the dielectric layer 30 direct contacts the channel layer 15 and fills the plurality of trenches T1 of the channel layer 15, the gate 40 includes a plurality of protruding sections 40b and a plurality of extending sections 40a directly contacting the dielectric layer 30. The patterned 3-dimensional gate geometry as shown in FIGS. 6-10 allows the power device to achieve increased effective gate width, for example, L2×2×m+L1 so as to obtain increased channel conductivity per unit length. In addition, as shown in FIGS. 6-7, the dielectric layer 30 includes a repeating conformal rectangular-wave structure/shape disposed along the x-axis direction, which is substantially parallel with the source electrode 45 and the drain electrode 50, respectively. Referring to FIGS. 9 and 10, the dielectric layer 30 is of a conformal U-shaped material layer disposed along an x-axis (substantially parallel with the drain electrode 50 or the source electrode 45, respectively) having different heights at different cross-sectional views. Referring to FIGS. 7-10, FIG. 9 is a cross-sectional view taken along a section 2-2 of the power device shown in FIGS. 7-8 to show the dielectric layer 30 being of a reduced height H1, while FIG. 10 is a cross-sectional view taken along a section 3-3 of the power device shown in FIGS. 7-8 to show the dielectric layer 30 being of a larger height H2. The different heights at different portions of the dielectric layer 30, for example, H1 and H2 can be between 20 nm to 150 nm. Referring to FIG. 9, the dielectric layer 30 extends through the barrier layer (AlGaN layer) 20, and stops at the top surface S1 of the channel layer (the u-GaN layer) 15. Referring to FIG. 10, the dielectric layer 30 extends through the barrier layer (AlGaN layer) 20 and a portion of the channel layer (the u-GaN layer) 15, and stops at a depth of about 50 nm to 100 nm from the top surface S1 of the channel layer (the u-GaN layer) 15.

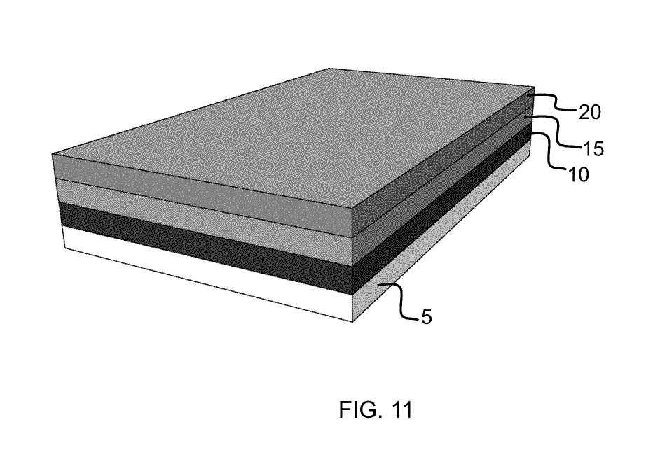

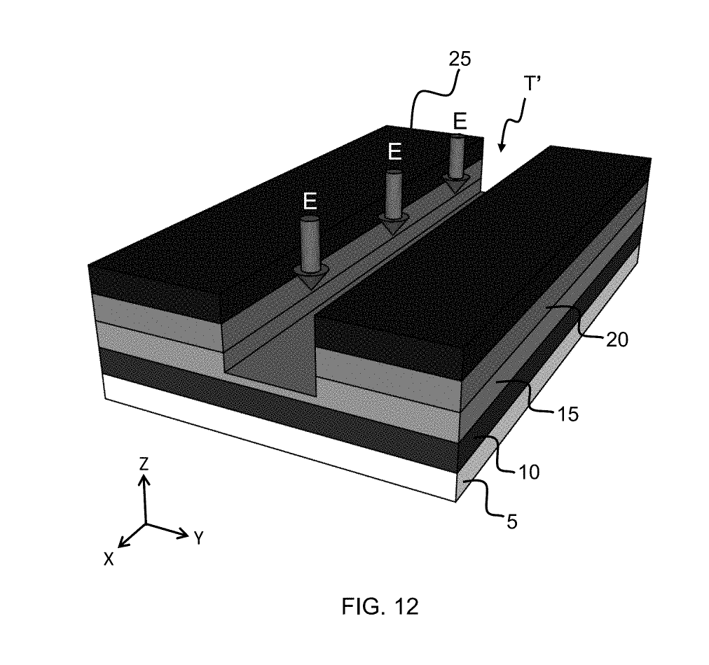

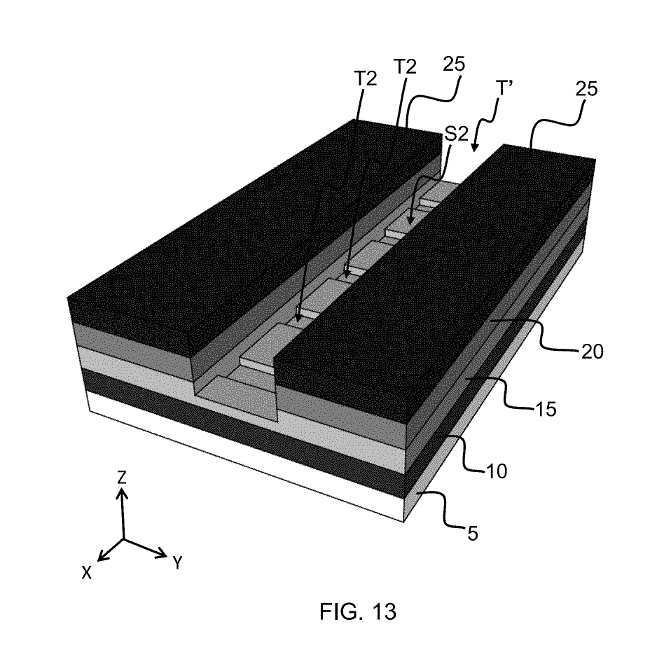

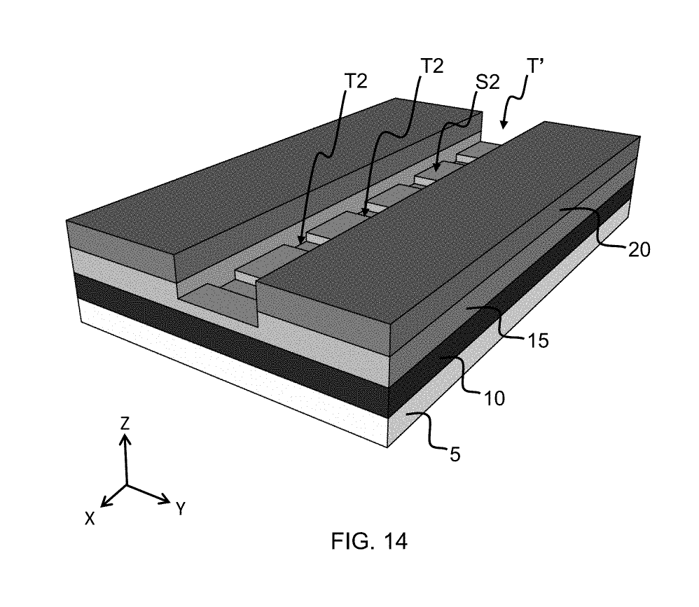

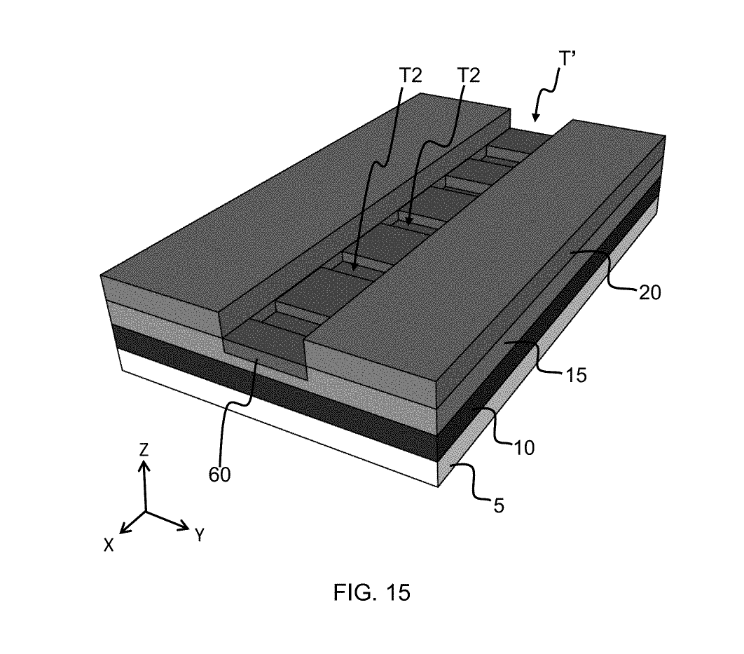

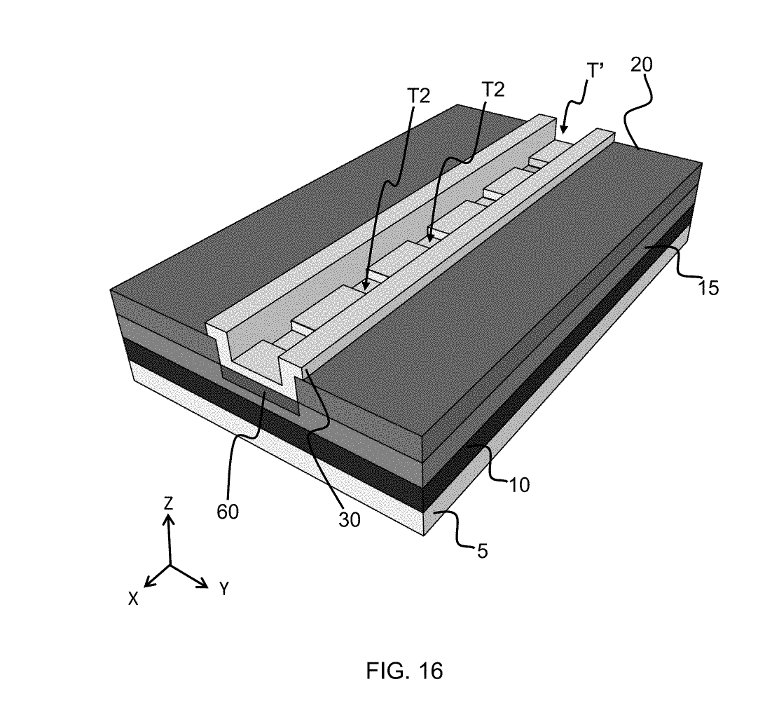

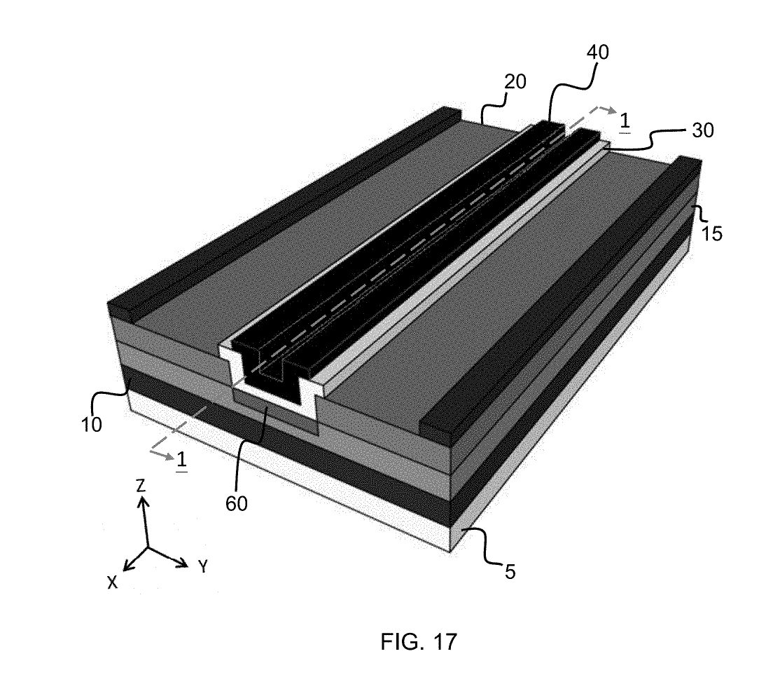

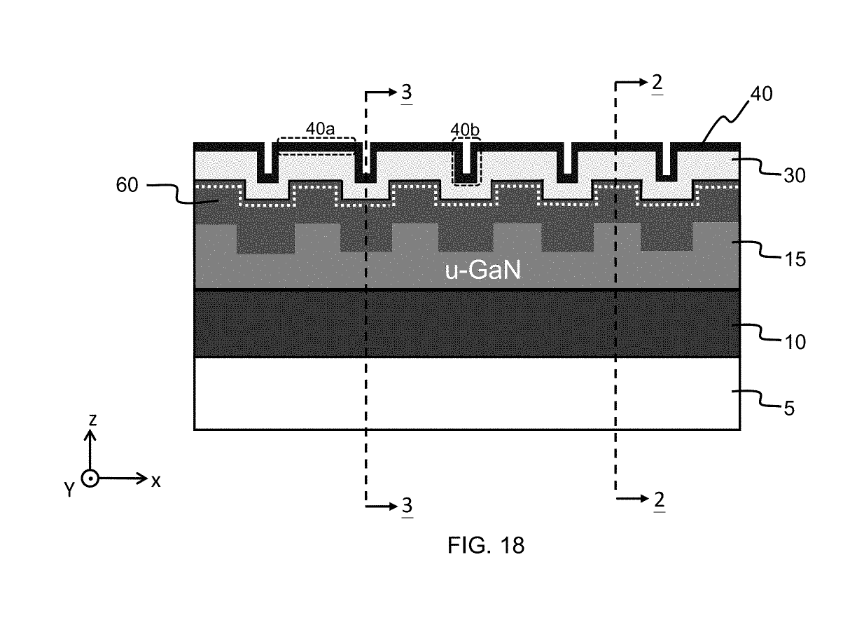

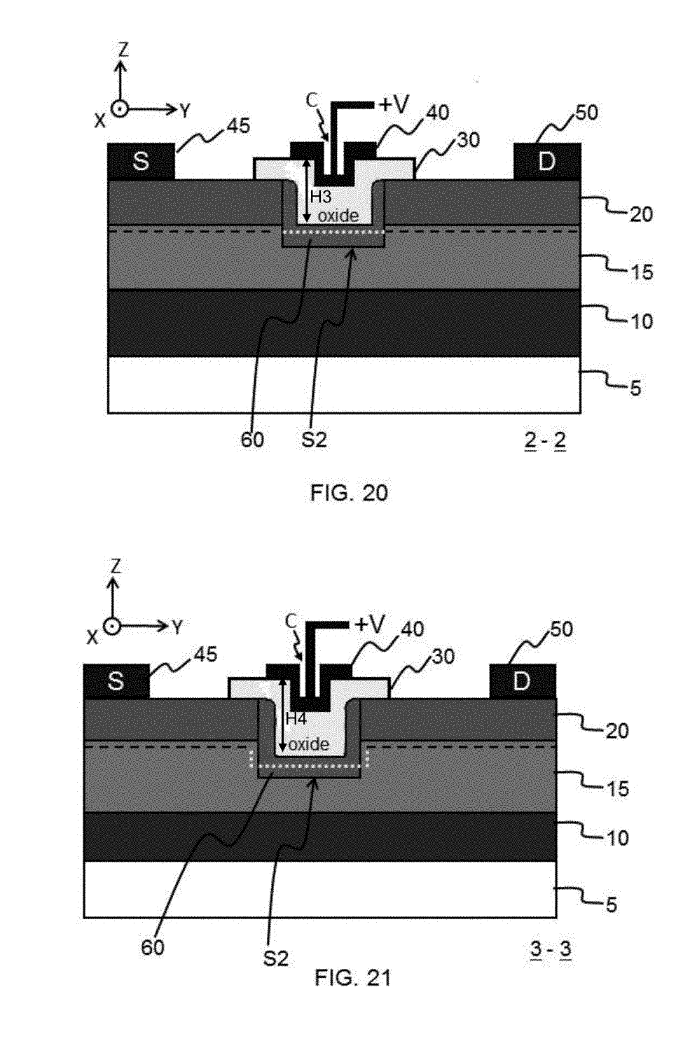

In accordance with another embodiment of present application, referring to FIGS. 11-21, a power device of a HEMT having a patterned three-dimensional gate geometry is fabricated by following steps. As shown in FIG. 11, in step (a), a buffer layer 10, a channel layer 15, and a barrier layer 20 are respectively grown on a substrate layer 5 in sequential order. The substrate layer 5 can be, for example, silicon (Si) substrate. The buffer layer 10 can be one or more sequential group-III nitride layers, with the group-III including one or more of In, Ga, and Al, such as, for example, gallium nitride (GaN). Meanwhile, the channel layer 15 can be a first group IIIA-VA compound semiconductor material, such for example, an u-GaN layer 15, and the barrier layer 20 can be a second group IIIA-VA compound semiconductor material, for example, an AlGaN layer 20. Later as shown in FIG. 12, in step (b), a trench T′ is formed by an etching process, for example, a dry-etching process E (shown as three-dimensional arrow structures labeled E in FIG. 12) through the barrier layer 20 and a portion of the channel layer 15 using photolithography techniques together with a hard mask 25, for example, a SiO₂ hard mask 25 formed by chemical vapor deposition. As shown in FIG. 13, in step (c1), the channel layer 15 is further patterned to form a plurality of trenches T2, respectively that are configured and arranged along an x-axis direction using photolithography and dry etching technique. As shown in FIG. 14, the SiO₂ hard mask 25 is then removed using wet etching with hydrofluoric acid (HF). As shown in FIG. 15, in step (c2), after removing the hard mask 25, a p-doped first group IIIA-VA compound semiconductor material filled region 60 is regrown in a gate region (not labeled) corresponding to locations of the trench T′ and the plurality of trenches T2 in a conformal manner directly contacting the channel layer 15 and filling the plurality of the trenches T2 thereof using photolithography and metalorganic chemical vapour deposition (MOCVD), molecular beam epitaxy (MBE) or hydride vapour phase epitaxy (HVPE). The material of the p-doped first group IIIA-VA compound semiconductor material filled region 60 can be, for example, p-GaN. Thickness of the p-doped first group IIIA-VA compound semiconductor material filled region 60 can be about 50 nm to 100 nm. Referring to FIG. 16 showing step (d), a dielectric layer 30 is grown or formed in the gate region (not labeled) in a conformal manner along the x-axis direction, directly contacts the p-doped first group IIIA-VA compound semiconductor material filled region 60 and fills a portion of the plurality of trenches T2 of the channel layer 15 and the trenches (not labeled) formed by the dielectric layer 30, corresponding to the plurality of trenches T2 of the channel layer 15. The dielectric layer 30 is formed by means of photolithography technique, in which the dielectric layer 30 can be silicon dioxide material, silicon nitride material, or other high-k dielectric material, and is deposited by an atomic layer deposition (ALD) process or a chemical vapor deposition (CVD) process. Meanwhile, FIGS. 18, 20 and 21 are cross-sectional views taken along sections 1-1, 2-2, and 3-3 of the power device shown in FIGS. 17-19, respectively. Thickness of the dielectric layer 30 can be 10 nm to 50 nm. Then, as shown in FIGS. 18, 20 and 21, in steps (e) and (f), a gate 40 is formed on the dielectric layer 30 in the gate region, and a source electrode 45 and a drain electrode 50 are respectively formed on the barrier layer 20. In particular as shown in FIG. 18, the gate 40 is extended along the x-axis direction with different depths thereof, in which the gate 40 includes a plurality of extending sections 40a and a plurality of protruding sections 40b directly contacting the dielectric layer 30. Furthermore, the dielectric layer 30 includes a repeating rectangular-wave structure conformally disposed along the x-axis direction that is substantially parallel with the source electrode 45 and the drain electrode 50, respectively, in which the protruding sections of the gate 40 fill the repeating rectangular-wave structure of the dielectric layer 30 along the x-axis direction shown in FIG. 18. The protruding sections 40b and the extending sections 40a of the gate 40 of the various embodiments are similar, and thus redundant details thereof are omitted. The gate 40 can be made of a metal or alloy such as, for example, copper, nickel/gold, or tungsten. The source electrode 45 and the drain electrode 50 are made of the same material, which can be metal, such as, for example, titanium, copper, silver, tungsten, aluminum, gold, or any of their compounds. Due to the interaction between the dielectric layer 30 and the p-GaN material filled region 60, upon the gate 40 being exerted under a positive bias voltage, the dielectric layer 30 grown on the p-GaN material filled region 60 can reverse electrons, for conducting current flow. Accordingly, reversed electrons, formed in the p-GaN material filled region 60 near an interface between the dielectric layer 30 and the p-GaN material filled region 60, as shown in FIGS. 18, 20 and 21 indicated by the white dotted lines. In the embodiment, because the power device includes the plurality of trenches T2, thus the interface of the dielectric layer 30 and the p-GaN material filled region 60 includes side interface portions and planar interface portions. Specifically, in the embodiment, a ratio of a total area of the side interface portions to that of the planar interface portions can be L2′×2×m′/L1′, wherein L2′ is a depth of one of the plurality of trenches T2, m is a number of the plurality of trenches T2, and L1′ is the gate width. In the embodiment, L2′ can be 50 nm, L1′ can be 2200 nm, m′ can be 5, and the above mentioned ratio can be greater than 0.2. Comparing the power device of the embodiment with a power device without patterned trenches in a channel layer, since electrons of the power device of the application can further be reversed near the side interface portions, thus an increased current ratio of the application can also be L2′×2×m′/L1′ which means the ideal increased current ratio can be approximately 0.2 corresponding to the ratio mentioned above. Thus the current is increased by at least 20%. However, in consideration other conditions, for example, the mobility of the accumulated electrons in a z-axis different from that of in a x-axis, the increased current ratio can be approximately increased by at least 0.1. Moreover, due to a difference in lattice constants, the barrier layer 20 grown on the u-GaN channel layer 15 can produce a piezoelectric polarization effect. Additionally, materials of the u-GaN channel layer 15, for example, GaN and the barrier layer 20, for example, AlGaN can produce spontaneous polarization effect. With these polarization effects, a two-dimensional electron gas is formed in the u-GaN channel layer 15 near an interface of the u-GaN channel layer 15 and the barrier layer 20, as shown in FIGS. 20-21 indicated by the black broken lines. In the illustrated embodiment as shown in FIGS. 20 and 21, the dielectric layer 30 forms a gate oxide (“oxide”), and the gate oxide directly contacts a top surface S2 of the p-doped first group IIIA-VA compound semiconductor material filled region 60.

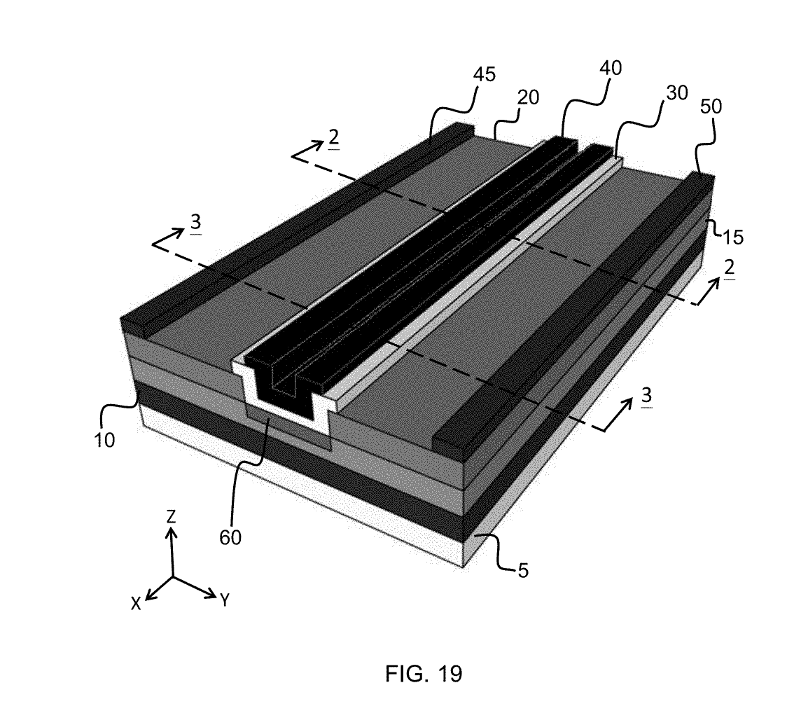

Referring to FIG. 19, at the completion of the fabrication method of the power device, the power device, which is an AlGaN/GaN HEMT, according to the another embodiment of present application having a patterned 3-dimensional gate geometry is fabricated. The power device of the illustrated embodiment includes a substrate layer 5, a buffer layer 10, a channel layer 15 disposed on the buffer layer 10, a barrier layer 20 disposed on the channel layer 15, a dielectric layer 30, a p-doped first group IIIA-VA compound semiconductor material filled region 60, a gate 40 disposed on the dielectric layer 30, the dielectric layer 30 disposed on the barrier layer 20 and the p-doped first group IIIA-VA compound semiconductor material filled region 60, respectively, a source electrode 45, and a drain electrode 50. A plurality of trenches T2 is formed by patterning the channel layer 15, the dielectric layer 30 directly contacts the p-doped first group IIIA-VA compound semiconductor material filled region 60 and fills the plurality of trenches T2 of the channel layer 15, the gate 40 includes a plurality of extending sections 40a and a plurality of protruding sections 40b directly contacting the dielectric layer 30. The patterned 3-dimensional gate geometry as shown in FIGS. 17-21 allows the power device (HEMT) to achieve increased effective gate width, for example, L2′×2×m′+L1′ so as to obtain increased channel conductivity per unit length. In addition, the dielectric layer 30 includes a repeating conformal rectangular-wave structure/shape disposed along the x-axis direction, which is substantially parallel with the source electrode 45 and the drain electrode 50, respectively. Moreover, the above-mentioned side interface portions and planar interface portions corresponding to the repeating rectangular-wave structure. Notably, the cavity structures C of the gate 40 (in the middle regions thereof) as shown and identified in FIG. 18, as well as shown in FIGS. 20 and 21 are not visible in FIGS. 17 and 19 (for example, in FIG. 18, there are 5 cavity structures for the gate 40), due to the fact that other portion of the gate 40 in FIG. 19 obstruct direct view of these cavity structures C. Referring to FIGS. 20 and 21, the dielectric layer 30 is of a conformal U-shaped material layer disposed along a x-axis (substantially parallel with the drain electrode or the source electrode, respectively) having different heights at different cross-sectional views. FIG. 20 is a cross-sectional view taken along a section 2-2 of the power device shown in FIGS. 18-19 to show the dielectric layer 30 being of a reduced height H3; and FIG. 21 is a cross-sectional view taken along a section 3-3 of the power device shown in FIGS. 18-19 to show the dielectric layer 30 being of a larger height H4. The different heights of the dielectric layer 30, for example, H3 and H4 can be between 20 nm to 150 nm. Referring to FIG. 20, the dielectric layer 30 extends through the barrier layer 20 (AlGaN layer), and stops at the top surface S2 of the channel layer 15 (the u-GaN layer) on the p-doped first group IIIA-VA compound semiconductor material filled region 60. Referring to FIG. 21, the dielectric layer 30 extends through the barrier layer 20 (AlGaN layer) and a portion of the channel layer 15 (the u-GaN layer), and stops at a depth of about 50 nm to 100 nm from the top surface S2 of the channel layer 15 (the u-GaN layer) onto the p-doped first group IIIA-VA compound semiconductor material filled region 60.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A power device, comprising:
a substrate layer;
a buffer layer;
a channel layer disposed on the buffer layer and comprising a first group IIIA-VA compound semiconductor material;
a barrier layer disposed on the channel layer and comprising a second group IIIA-VA compound semiconductor material;
a dielectric layer;
a gate disposed on the dielectric layer, the dielectric layer disposed on the channel layer, respectively;
a source electrode; and
a drain electrode,
wherein the channel layer comprises a plurality of trenches, the dielectric layer directly contacts the channel layer and fills the plurality of trenches, and the gate comprises a plurality of protruding sections and a plurality of extending sections directly contacting the dielectric layer.

2. The power device as claimed in claim 1, wherein the channel layer comprises an undoped GaN layer, the barrier layer comprises an AlGaN layer.

3. The power device as claimed in claim 1, wherein the power device comprises a high-electron-mobility transistor (HEMT).

4. The power device as claimed in claim 1, wherein the dielectric layer comprises a repeating rectangular-wave structure conformally disposed along a direction substantially parallel with the source electrode and the drain electrode, respectively.

5. The power device as claimed in claim 1, wherein the dielectric layer forms a gate oxide, and the gate oxide directly contacts a top surface of the channel layer and the plurality of trenches, respectively.

6. The power device as claimed in claim 1, wherein an interface between the dielectric layer and the channel layer comprises side interface portions and planar interface portions corresponding to the plurality of trenches, and a ratio of a total area of the side interface portions to that of the planar interface portions is greater than 0.2.

7. The power device as claimed in claim 6, wherein a width of the gate (gate width) is about 2200 nm, and a depth of one of the plurality of trenches is about 50 nm.

8. A power device, comprising:
a substrate layer;
a buffer layer;
a channel layer disposed on the buffer layer and comprising a first group IIIA-VA compound semiconductor material;
a barrier layer disposed on the channel layer and comprising a second group IIIA-VA compound semiconductor material;
a dielectric layer;
a p-doped first group IIIA-VA compound semiconductor material filled region;
a gate disposed on the dielectric layer, the dielectric layer disposed on the p-doped first group IIIA-VA compound semiconductor material filled region, respectively;
a source electrode; and
a drain electrode,
wherein the channel layer comprises a plurality of trenches, the dielectric layer directly contacts the p-doped first group IIIA-VA compound semiconductor material filled region, the p-doped first group IIIA-VA compound semiconductor material filled region is conformally disposed on and directly contacts a top surface of the channel layer and fills the plurality of trenches of the channel layer, and the gate includes a plurality of protruding sections and a plurality of extending sections directly contacting the dielectric layer, respectively.

9. The power device as claimed in claim 8, wherein the channel layer comprises an undoped GaN layer, the barrier layer comprises an AlGaN layer, and the p-doped first group IIIA-VA compound semiconductor material filled region comprises p-GaN.

10. The power device as claimed in claim 8, wherein the dielectric layer forms a gate oxide, and the gate oxide is disposed directly on the p-doped first group IIIA-VA compound semiconductor material filled region and in the plurality of trenches.

11. The power device as claimed in claim 8, the dielectric layer includes a repeating rectangular-wave structure conformally disposed along a direction substantially parallel with the source electrode and the drain electrode respectively, and the p-doped first group IIIA-VA compound semiconductor material filled region comprises an alternating repeating rectangular-wave structure conformally disposed along the direction substantially parallel with the source electrode and the drain electrode, respectively.

12. The power device as claimed in claim 11, wherein an interface between the p-doped first group IIIA-VA compound semiconductor material filled region and the dielectric layer includes side interface portions and planar interface portions corresponding to the repeating rectangular-wave structure of the dielectric layer, and a ratio of a total area of the side interface portions to that of the planar interface portions is greater than 0.2.

13. A method for fabricating a power device, comprising steps of:
(a) growing a buffer layer, a channel layer, and a barrier layer on a substrate layer in sequential order;
(b) forming a first trench by etching the barrier layer;
(c) patterning the channel layer to form a plurality of second trenches therein using photolithography and etching;
(d) growing a dielectric layer in a gate region in a conformal manner;
(e) forming a gate on the dielectric layer in the gate region; and
(f) forming a source electrode and a drain electrode respectively on the barrier layer,
wherein the channel layer comprises a first group IIIA-VA compound semiconductor material; the barrier layer comprises a second group IIIA-VA compound semiconductor material, the gate comprises a plurality of protruding sections and a plurality of extending sections directly contacting the dielectric layer, the dielectric layer comprises a repeating rectangular-wave structure conformally disposed along a direction substantially parallel with the source electrode and the drain electrode, respectively, and the protruding sections of the gate fill the repeating rectangular-wave structure of the dielectric layer.

14. The method for fabricating the power device as claimed in claim 13, wherein the gate region corresponds to locations of the first trench and the plurality of second trenches.

15. The method for fabricating the power device as claimed in claim 13, wherein the channel layer comprises an undoped GaN layer, the barrier layer comprises an AlGaN layer, the power device comprises an high-electron-mobility transistor (HEMT).

16. The method for fabricating the power device as claimed in claim 13, wherein in the step (b), the first trench is formed by etching through the barrier layer to stop on a top surface of the channel layer.

17. The method for fabricating the power device as claimed in claim 15, wherein in the step (d), the dielectric layer directly contacts a top surface of the channel layer and fills the plurality of second trenches of the channel layer.

18. The method for fabricating the power device as claimed in claim 13, wherein in the step (b), the first trench is formed by etching through the barrier layer and a portion of the channel layer.

19. The method for fabricating the power device as claimed in claim 17, between the step (c) and the step (d), further comprising a step of regrowing a p-doped first group IIIA-VA compound semiconductor material filled region in the gate region in a conformal manner directly contacting the channel layer and filling the plurality of second trenches of the channel layer, and wherein the dielectric layer directly contacts the p-doped first group IIIA-VA compound semiconductor material conformal filled region.

20. The method for fabricating the power device as claimed in claim 18, wherein the first trench is formed by dry etching, and the p-doped first group IIIA-VA compound semiconductor material filled region is a conformally filled structure made of p-GaN.
